(19) United States
(12) Patent Application Publication
(10) Pub. No.: US 2026/0255659 A1
(43) Pub. Date: Aug. 27, 2026

(54) HEMT TRANSISTOR

(71) Applicant: STMICROELECTRONICS INTERNATIONAL N.V., Geneva (CH)

(72) Inventors: Aurore CONSTANT, Tours (FR); Mohammed ZEGHOUANE, Tours (FR); Ferdinando IUCOLANO, Gravina di Catania (IT)

(21) Appl. No.: 19/535,660

(22) Filed: Feb. 10, 2026

(30) Foreign Application Priority Data
Feb. 24, 2025 (FR) 2501892

(51) Int. Cl. H10D 84/01; H10D 30/01; H10D 30/47; H10D 30/67; H10D 62/85

(52) U.S. Cl. CPC H10D 84/0177; H10D 30/015; H10D 30/475; H10D 30/6755; H10D 62/8503

(57) ABSTRACT

The present disclosure relates to a HEMT transistor. An example HEMT transistor comprises: a first semiconductor layer and a gate arranged on a first surface of the first semiconductor layer. The gate comprises an alternation of at least two first layers and of at least three second layers. The first layers being doped with magnesium and with at least one of the dopant elements selected from among silicon and oxygen and the first layers having a dopant element concentration higher than the dopant element concentration in the second layers.

### CROSS REFERENCE TO RELATED APPLICATIONS

This application claims the priority benefit of French Patent application number FR2501892, filed on February 24, 2025, entitled “TRANSISTOR HEMT” which is hereby incorporated by reference to the maximum extent allowable by law.

### TECHNICAL FIELD

The present disclosure generally concerns the field of transistors and more particularly the field of high electron mobility transistors also called HEMT.

### BACKGROUND

HEMT transistors are based on a surface heterojunction from which a two-dimensional electron gas, called 2DEG, is formed.

There exists a need to improve HEMT transistors and their manufacturing methods.

### BRIEF SUMMARY

For this purpose, an embodiment provides a transistor HEMT comprising:

a first semiconductor layer; and

a gate arranged on a first surface of the first semiconductor layer,

wherein the gate comprises an alternation of at least two first layers and of at least three second layers, the first layers being doped with magnesium and with at least one of the dopant elements selected from among silicon and oxygen and the first layers having a dopant element concentration higher than the dopant element concentration in the second layers.

According to an embodiment, the gate comprises at least four first layers and at least five second layers.

According to an embodiment, each first layer is in contact with an overlying second layer and an underlying second layer.

According to an embodiment, the magnesium concentration in the first layers is higher than 1.10¹⁷ atoms/cm³.

According to an embodiment, the oxygen and/or silicon concentration in the first layers is higher than 1.10¹⁶ atoms/cm³.

According to an embodiment, the magnesium concentration in the second layers is lower than 1.10¹⁷ atoms/cm³.

According to an embodiment, the lower surface of the gate corresponds to the lower surface of a second lower layer.

According to an embodiment, the upper surface of the gate corresponds to the upper surface of a second upper layer.

According to an embodiment, the second upper layer has a greater thickness than the other second layers of the gate.

According to an embodiment, the gate comprises, between the second upper layer and a first lower layer, an aluminum nitride layer, said aluminum nitride layer being in contact with the second upper layer.

According to an embodiment, the second layers all have the same thickness.

According to an embodiment, the gate further comprises an alternation of at least two third layers and of at least three fourth layers, the third layers being predominantly doped with silicon and/or oxygen dopant elements, and the third layers having a dopant element concentration higher than the dopant element concentration in the fourth layers, the alternation of the first and second layers being arranged in a lower portion of the gate and the alternation of the third and fourth layers being arranged in an upper portion of the gate, and the first layers being predominantly doped with magnesium dopant elements.

Another embodiment provides a method of forming an HEMT transistor comprising the following successive steps:

a) forming a first semiconductor layer;

b) forming at least two first layers in alternation with at least three second layers so as to create a gate on a first surface of the first semiconductor layer, the first layers being doped with magnesium and with at least one of the dopant elements selected from among silicon and oxygen, and the first layers having a dopant element concentration higher than the dopant element concentration in the second layers.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 is a partial and simplified cross-section view of an example of an HEMT transistor;

FIG. 2 is a partial and simplified cross-section view of an example of an HEMT transistor according to a first embodiment;

FIG. 3 is a partial and simplified cross-section view of an example of an HEMT transistor according to a second embodiment;

FIG. 4 is a partial and simplified cross-section view of an example of an HEMT transistor according to a third embodiment;

FIG. 5 is a partial and simplified cross-section view of an example of an HEMT transistor according to a fourth embodiment;

FIG. 6 is a partial and simplified cross-section view of an example of an HEMT transistor according to a fifth embodiment; et

FIG. 7 is a partial and simplified cross-section view of an example of an HEMT transistor according to a sixth embodiment.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the applications that the described HEMT transistors may have are not detailed, the embodiments being compatible with usual applications of HEMT transistors. The field of so-called power HEMT transistors, capable of holding relatively high voltages in the off state, for example voltages in the order of from 100 to 650 volts, is more particularly considered herein. The described transistors may, for example, be used in various power conversion or scaling circuits, for example in industrial equipment, display or illumination devices, telecommunications equipment, automotive devices, etc.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as "front", "back", "top", "bottom", "left", "right", etc., or relative position qualifiers, such as "top", "bottom", "upper", "lower", etc., or orientation qualifiers, such as "horizontal", "vertical", etc., reference is made unless otherwise specified to the orientation of the drawings.

Unless specified otherwise, the expressions "about", "approximately", "substantially", and "in the order of" signify plus or minus 10% or 10°, preferably of plus or minus 5% or 5°.

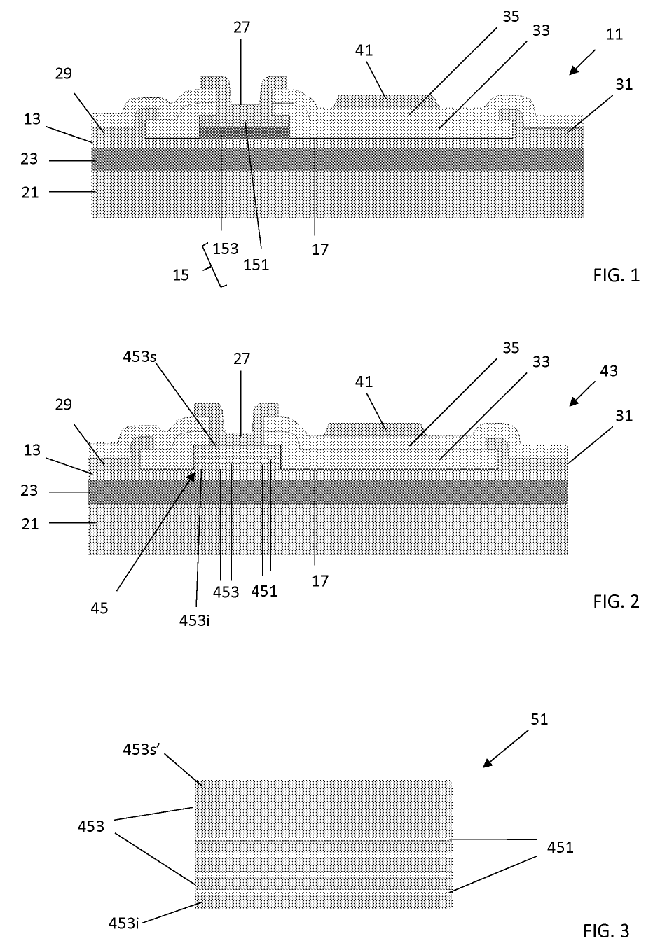

FIG. 1 is a partial and simplified cross-section view of an example of an HEMT transistor 11 according to an embodiment.

HEMT transistor 11 comprises a first semiconductor layer 13 called barrier layer, arranged on a second conductive layer 23 called channel layer. Semiconductor layer 23 is for example in contact, by its lower surface, with the upper surface of conductive layer 23. As an example, the stack comprising semiconductor layer 13 and semiconductor layer 23 rests on a substrate 21. Semiconductor layer 23 is for example in contact, by its lower surface, with the upper surface of substrate 21. The interface between semiconductor layer 13 and semiconductor layer 23 defines a heterojunction at the surface of which a two-dimensional electron gas 2DEG, also called electron channel, is formed.

Semiconductor layers 13 and 23 are for example made of type III-V semiconductor materials, for example based on gallium nitride (GaN). Semiconductor layer 13 is for example made of aluminum-gallium nitride (AlGaN). Semiconductor layer 13 is for example made of gallium nitride (GaN).

As an example, substrate 21 is made of a semiconductor material. Substrate 21 is for example made of silicon, or of silicon carbide. As a variant, substrate 21 is made of aluminum nitride. Substrate 21 for example comprises, on its upper surface side, a buffer layer, not detailed in the drawings, for example made of gallium nitride. The buffer layer is for example in contact, by its upper surface, with the lower surface of semiconductor layer 23.

HEMT transistor 11 comprises a gate 15 on the upper surface of semiconductor layer 13. Gate 15 is for example in contact, by its lower surface, with the upper surface of semiconductor layer 13.

Gate 15 is for example made of a semiconductor material, for example of a type III-V semiconductor material, for example of gallium nitride. As an example, gate 15 is made of an aluminum-gallium nitride having its chemical formula corresponding to AlxGax-1N, where x is a positive integer.

As an example, gate 15 has a total thickness within the range from 20 nm to 200 nm, for example within the range from 80 nm to 120 nm, for example in the order of 100 nm.

The gate 15 of transistor 11 for example comprises an upper portion 151 and a lower portion 153.

The upper portion 151 of gate 15 comprises N-type dopant elements, for example oxygen or silicon atoms. The lower portion 153 of gate 15 comprises P-type dopant elements, for example magnesium atoms. This enables to define a PN junction at the interface between lower portion 153 and upper portion 151.

As an example, upper portion 151 has a thickness in the range from 10 nm to 100 nm, for example in the range from 30 nm to 70 nm, for example in the order of 50 nm.

As an example, HEMT transistor 11 further comprises a source contact metallization 29 and a drain contact metallization 31. As an example, contact metallizations 29 and 31 are based on titanium, on titanium nitride, and/or on an aluminum and copper alloy. The source 29 and drain 31 contact metallizations for example each define an ohmic contact with semiconductor layer 13. Contact metallizations 29 and 31 are for example located on top of and in contact with semiconductor layer 13, on either side of gate 15.

HEMT transistor 11 further comprises a passivation layer 17 covering the flanks of gate 15, a portion of the upper surface of gate 15, and continuing over a portion of the upper surface of semiconductor layer 13 not covered with gate 15. As an example, passivation layer 17 is in contact, by its lower surface, with the upper surface of semiconductor layer 13. Passivation layer 17 is for example further in contact with the flanks of gate 15. In the embodiment of FIG. 1, passivation layer 17 extends laterally between the source 29 and drain 31 contact metallizations.

Passivation layer 17 for example has a thickness in the range from 2 nm to 20 nm, for example in the range from 2 nm to 10 nm, for example in the order of 5 nm. Passivation layer 17 is for example made of a dielectric material, for example of alumina (Al₂O₃), of silicon dioxide (SiO₂), of silicon nitride (Si₃N₄), of aluminum nitride (AlN), or of hafnium oxide (HfO₂).

Gate 15 is for example topped by a gate contact metallization 27.

As an example, gate contact metallization 27 is in contact, by its lower surface, with the upper surface of gate 15. Gate contact metallization 27 then extends through the layer 17 which only covers the upper surface of gate 15 on its periphery.

As an example, gate contact metallization 27 is based on titanium nitride and/or on titanium, and/or on tantalum, and/or an alloy of tungsten and tantalum and/or an alloy of tungsten and titanium and/or of an aluminum and copper alloy.

In this example, metallization 27 defines a Schottky contact with semiconductor gate 15. Semiconductor gate 15 and metallization 27 define a Schottky diode having its anode corresponding to semiconductor gate 15 and having its cathode corresponding to metallization 27.

HEMT transistor 11 for example comprises a plurality of levels of insulating layers inside of, and for example on top of, which metallizations are formed.

As an example, HEMT transistor 11 comprises an insulating layer 33 on top of and in contact with the upper surface of passivation layer 17. As an example, insulating layer 33 covers the entire surface of passivation layer 17. Insulating layer 33 is for example open in front of a central portion of the upper surface of gate 15 to be crossed by gate contact metallization 27. Insulating layer 33 is for example made of a dielectric material, for example of an oxide, for example of silicon dioxide (SiO₂), or of silicon nitride (Si₃N₄).

As an example, source contact metallization 29 continues on the upper surface of insulating layer 33 towards gate 15, without reaching gate 15. As an example, drain contact metallization 31 continues on the upper surface of insulating layer 33 towards gate 15, without reaching gate 15.

HEMT transistor 11 may comprise a second insulating layer 35 covering the entire structure and more particularly, layer 33 and the source 29 and drain 31 contact metallizations. The second insulating layer 35 is, for example, made of the same material as insulating layer 33.

HEMT transistor 11 may further comprise a metal region 41 formed on top of, and for example in contact with, insulating layer 35 between metallizations 27 and 31. As an example, metal region 41 is based on titanium nitride and/or on titanium, and/or on tantalum, and/or an alloy of tungsten and tantalum and/or an alloy of tungsten and titanium and/or on an aluminum and copper alloy.

Metal region 41 for example has the function of modifying the profile of the electric field distribution of the gate edge, located on the drain side (the right edge of the gate in FIG. 1), and to decrease the critical electric field peak, thus increasing the avalanche voltage. Metal regions 41 are for example referred to as "field plates".

In the transistor of FIG. 1, the 2DEG channel is for example normally off, that is, it is interrupted under gate 15, which prevents the flowing of a current between the source and the drain of the transistor. The transistor is said to be in the off state. The channel can be restored (that is, turned on) by the biasing of gate 15. In this case, a current may be created between the source and the drain of the transistor. The described embodiments may also apply to normally-on transistors.

While passivation layer 17 plays an important role in the transistor quality and lifetime, its presence may cause the accumulation of electrons along the flanks of gate 15, under passivation layer 17. This phenomenon is for example enhanced by the damaging of the flanks of the gate caused by the etching of gate 15. This results in the appearing of leakage currents between gate contact metallization 27 and the source 29 and/or drain 31 metallizations, running through the flanks of the gate.

The presence of a PN junction in gate 15 enables to decrease this phenomenon. Contact metallization 27 then forms an ohmic contact with the N-type upper portion 151 of semiconductor gate 15. Thus, the Schottky diode formed, in the example of FIG. 1, between semiconductor gate 15 and metallization 27, is replaced with a PN diode formed between the lower portion and the upper portion of semiconductor gate 15.

However, a clear junction between the upper portion 151 and the lower portion 153 of gate 15 is difficult to obtain since the magnesium atoms present in the lower portion 153 of gate 15 tend to diffuse into the upper portion 151 of gate 15, which generates a modification of the doping of the upper portion 151 of gate 15.

FIG. 2 is a partial and simplified cross-section view of an example of an HEMT transistor 43 according to a first embodiment.

The transistor 43 illustrated in FIG. 2 is similar to the transistor 11 illustrated in FIG. 1, with the difference that transistor 43 comprise a gate 45 comprising an alternation of a plurality of first layers 451 comprising P-type dopant elements, here, magnesium, and N-type dopant elements, here at least one selected from among silicon and oxygen and a plurality of second layers 453, the first layers 451 having a dopant element concentration higher than the dopant element concentration in the second layers 453. As an example, in layers 451, P-type dopant elements are predominant over N-type dopant elements.

The presence of silicon dopant elements and/or of silicon in layers 451 enables the hydrogen atoms present in layers 451 to bond to these dopant elements rather than to the magnesium dopant elements, leaving the magnesium dopant elements free, which generates, for a same concentration of magnesium dopant elements the increase of the P-type conductivity of layers 451.

As an example, gate 45 comprises at least 7 layers 451 alternated with at least 8 layers 453. As an example, gate 45 comprises at least 8 layers 451 alternated with at least 9 layers 453.

As an example, gate 45 comprises less than 10 layers 451 alternated with less than 11 layers 453. As an example, gate 45 comprises less than 9 layers 451 alternated with less than 10 layers 453.

Layers 451 for example have a magnesium concentration higher than 1.10¹⁷ atoms/cm³, for example in the range from 1.10¹⁹ atoms/cm³ to 3.10¹⁹ atoms/cm³. Layers 451 for example have an oxygen and/or silicon concentration higher than 1.10¹⁶ atoms/cm³, for example higher than 1.10¹⁷ atoms/cm³, for example in the order of 6.10¹⁷ atoms/cm³.

Layers 453 for example have a magnesium concentration lower than 1.10¹⁸ atoms/cm³, for example lower than 1.10¹⁷ atoms/cm³. Layers 451 for example have an oxygen and/or silicon concentration lower than 1.10¹⁶ atoms/cm³.

In FIG. 2, layers 451 and 453 for example extend along the entire length of gate 45. Layers 451 and 453 for example extend across the entire width of gate 45.

As an example, the lower surface of gate 45 is defined by a layer 453 designated with reference 453i. Layer 13 is for example in contact with gate 45 by layer 453i.

As an example, the upper surface of gate 45 is defined by a layer 453 designated with reference 453s. Metallization 27 is for example in contact with gate 45 by layer 453s.

Each of layers 451 is for example thus in contact, by its upper surface, with a layer 453 and, by its lower surface, with another layer 453.

As an example, layers 451 and 453 all substantially have the same thickness. Each layer 451 and 453 for example has a thickness in the range from 10 nm to 20 nm, for example in the order of 13 nm.

As an example, gate 45 is formed by epitaxy, for example at low temperature, for example at a temperature lower than 950°C. Gate 45 is for example formed during a step during which dopant elements are progressively implanted along the growth of gate 45 (in-situ doping). The forming of gate 45 for example comprises a succession of a plurality of doping cycles during the epitaxial growth of gate 45. As an example, each cycle enables to form a pair of layers 451 and 453.

Each cycle comprises, during a first period, the implantation of the magnesium dopant elements and of the silicon and/or oxygen dopant elements, which enables to form a layer 451, and comprises, during a second period, an absence of implantation of the dopant elements, which enables to form a layer 453. As an example, the number of cycles performed during this step is equal to the number of layers 451 and 453 desired and defined for gate 45.

FIG. 3 is a partial and simplified cross-section view, of an example of an HEMT transistor gate 51 according to a second embodiment.

The gate 51 illustrated in FIG. 3 is similar to the gate 45 of the transistor 43 illustrated in FIG. 2, with the difference that the gate 51 illustrated in FIG. 3 comprises, on its upper surface side, a layer 453s’ of same nature as the layer 453s of FIG. 2 but having a thickness greater than that of layer 453s. In other words, in the example of FIG. 3, upper layer 453s’ has a thickness greater than that of the other layers 453 in the stack.

As an example, layer 453s’ has a thickness in the range from 20 nm to 50 nm, for example in the order of 30 nm.

In the shown example, gate 51 comprises fewer layers 451 and layers 453 than what is provided in the gate 45 of FIG. 2.

As an example, gate 51 comprises at least 5 layers 451 alternated with at least 6 layers 453. As an example, gate 51 comprises at least 6 layers 451 alternated with at least 7 layers 453.

As an example, gate 51 comprises less than 9 layers 451 alternated with less than 10 layers 453. As an example, gate 51 comprises less than 7 layers 451 alternated with less than 8 layers 453.

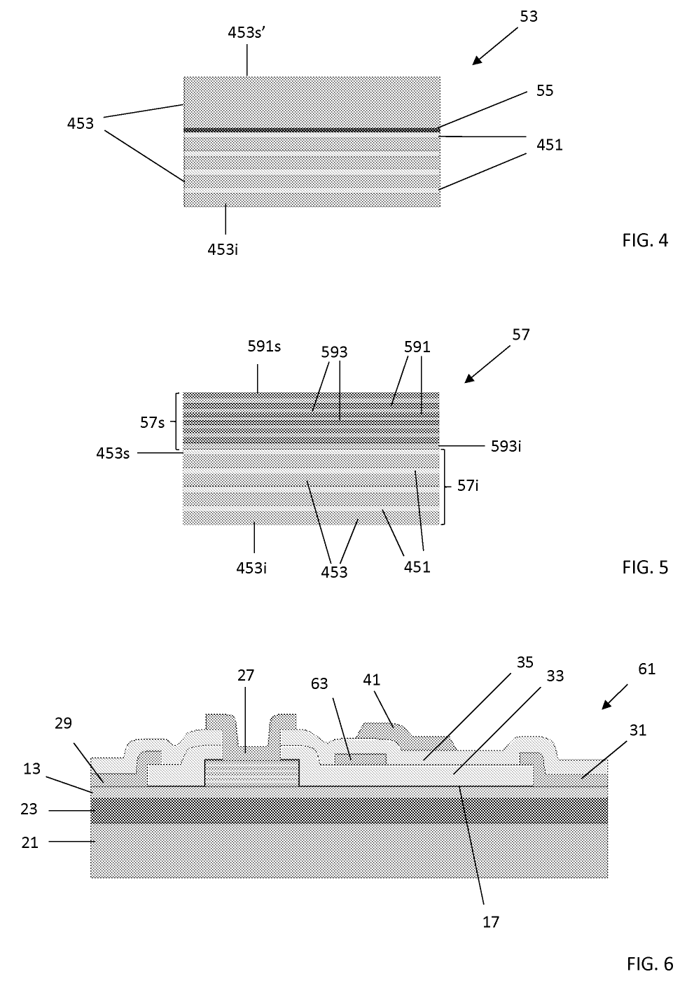

FIG. 4 is a partial and simplified cross-section view, of an example of an HEMT transistor gate 53 according to a third embodiment.

The gate 53 illustrated in FIG. 4 is similar to the gate 51 illustrated in FIG. 3, with the difference that the gate 53 illustrated in FIG. 4 further comprises, between upper layer 453s’ and the underlying layer 451, a stop layer 55 made of aluminum nitride (AlN). Layer 55 for example enables to prevent or to limit the diffusion of the magnesium of layer 451 into layer 453s’.

Stop layer 55 is for example in contact, by its upper surface, with upper layer 453s’. Stop layer 55 is further, for example, in contact, by its lower surface with the underlying layer 451.

Stop layer 55 for example extends along the entire length of gate 53. Stop layer 55 further for example extends across the entire width of gate 53. As an example, layer 55 has a thickness in the range from 10 nm to 15 nm, for example in the order of 13 nm.

FIG. 5 is a partial and simplified cross-section view of an example of an HEMT transistor gate 57 according to a fourth embodiment.

The gate 57 illustrated in FIG. 5 is similar to the gate 43 of the transistor 41 illustrated in FIG. 2, with the difference that a lower portion 57i of gate 57 comprises the alternation of layers 451 and 453 and that an upper portion 57s of gate 57 comprises an alternation of a plurality of third layers 591 predominantly doped with N-type dopant elements, here silicon and/or oxygen and of a plurality of fourth layers 593. In FIG. 5, the third layers 591 have a dopant element concentration greater than the dopant element concentration in the fourth layers 591.

Layers 591 for example have an oxygen and/or silicon concentration higher than 1.10¹⁷ atoms/cm³, for example in the order of 5.10¹⁸ atoms/cm³.

As an example, layers 591 for example have a magnesium concentration lower than 10¹⁶ atoms/cm³, for example lower that 10¹⁵ atoms/cm³. As an example, layers 591 comprise no magnesium atoms.

Layers 593 for example have an oxygen and/or silicon concentration lower than 1.10¹⁶ atoms/cm³.

As an example, layers 593 are identical to layers 453, with the difference that layers 593 are thinner than layers 453. As an example, layers 593 have a thickness in the range from 5 nm to 10 nm, for example in the order of 7 nm.

As an example, layers 591 each have a thickness substantially identical to the thickness of layers 593.

As an example, the upper portion 57s of gate 57 comprises at least 2 layers 591 alternated with at least 2 layers 593.

As an example, gate 57 comprises fewer layers 451 and 453 than what is provided in gate 45.

As an example, in the lower portion 57i of gate 57, gate 57 comprises at least 5 layers 451 alternated with at least 6 layers 453. As an example, in the lower portion 57i of gate 57, gate 57 comprises at least 6 layers 451 alternated with at least 7 layers 453.

As an example, in the lower portion 57i of gate 57, gate 57 comprises less than 9 layers 451 alternated with less than 10 layers 453. As an example, in the lower portion 57i of gate 57, gate 57 comprises less than 7 layers 451 alternated with less than 8 layers 453.

As an example, the upper surface of the upper portion 57s of gate 57 is defined by a layer 591 designated with reference 591s. As an example, the lower surface of the upper portion 57s of gate 57 is defined by a layer 593 designated with reference 593i.

As an example, the upper surface of the lower portion 57i of gate 57 is defined by a layer 451 designated with reference 451s. As an example, the lower surface of the lower portion 57i of gate 57 is defined by a layer 453 designated with reference 453i.

As an example, upper portion 57s and lower portion 57i are in contact with each other. More specifically, layer 593i is in contact with layer 451s. As an example, upper portion 57s extends over the entire length and width of gate 57.

As an example, the upper portion 57s of gate 57 has a thickness in the range from 10 nm to 50 nm, for example in the order of 30 nm. As an example, the lower portion 57i of gate 57 has a thickness in the range from 40 nm to 100 nm, for example in the order of 70 nm.

In this embodiment, the forming of gate 57 is for example similar to the forming of the gate 41 of transistor 43, with the difference that during the forming of gate 57, the magnesium doping stops.

As an example, a first part of the forming of gate 57 comprises the forming of the lower portion 57i of gate 57 similarly to what has been described for the forming of gate 45.

In a second part of the forming of gate 57, which corresponds to the forming of upper portion 57s, while the epitaxial growth is not interrupted after the first part of the forming of gate 57, a plurality of other doping cycles follow one another. In this second part, each cycle comprises, during a third time period, the implantation of silicon and/or of oxygen dopant elements enabling the forming of a layer 591, and comprises, during a fourth time period, the absence of implantation of dopant elements enabling to form a layer 593. As an example, the implantation of dopant elements for the forming of layers 591 does not comprise the implantation of magnesium elements. As a variant, the implantation of dopant elements for the forming of layers 591 comprises the implantation of magnesium elements in a concentration lower than the concentration of the silicon and/or oxygen dopant elements, for example in a concentration lower than 10¹⁴ atoms/cm³. As an example, the number of cycles carried out during this step is equal to the number of layers 591 and 593 desired and defined for gate 57.

FIG. 6 is a partial and simplified cross-section view of an example of an HEMT transistor 61 according to a fifth embodiment.

The transistor 61 illustrated in FIG. 6 is similar to the transistor 43 illustrated in FIG. 2, with the difference that transistor 61 comprises a metal region 63 extending over a portion of the surface of insulating layer 33. The metal region for example extends between insulating layers 35 and 33. As an example, metal region 63 extends between gate contact metallization 27 and drain contact metallization 31 without being in contact with metallizations 27 and 31.

As an example, metal region 63 is based on titanium nitride and/or on titanium, and/or on tantalum, and/or an alloy of tungsten and tantalum and/or an alloy of tungsten and titanium and/or on an aluminum and copper alloy. Metal region 63 is for example made of the same material as gate contact metallization 27.

Metal region 63 has, like region 41, for example for example the function of modifying the profile of the electric field distribution of the gate edge, located on the drain side (the right edge of the gate in FIG. 6), and to decrease the critical electric field peak, thus increasing the avalanche voltage. Metal region 63 is for example called "field plate".

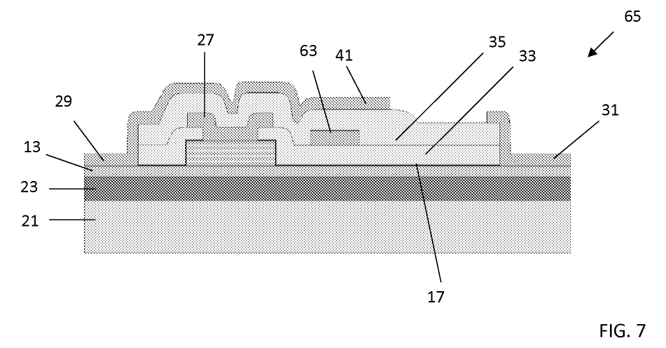

FIG. 7 is a partial and simplified cross-section view of an example an HEMT transistor 65 according to a sixth embodiment.

The transistor 65 illustrated in FIG. 7 is similar to the HEMT transistor 43 illustrated in FIG. 2 with the difference that, in the method of manufacturing transistor 65, the source 29 and drain 31 contact metallizations have been formed after the forming of gate contact metallization 27 while in the method of manufacturing transistor 41, the source 29 and drain 31 contact metallizations have been formed before the forming of gate contact metallization 27.

More particularly, in this example, transistor 65 is different from transistor 43 in that the source 29 and drain 31 contact metallizations run through layer 35 and in that layer 35 covers gate contact metallization 27.

Various embodiments and variants have been described. Those skilled in the art will understand that certain features of these various embodiments and variants may be combined, and other variants will occur to those skilled in the art. In particular, the second, third, and fourth embodiments illustrated in FIGS. 3, 4, and 5, may be combined with one another and with the fifth and sixth embodiments illustrated in FIGS. 6 and 7.

Further, although an example of embodiment in which the transistor gate is in contact with the upper surface of upper semiconductor layer 13 has been described hereabove, as a variant, the gate may be separated from the semiconductor layer 13 by a gate insulator layer.

Finally, the practical implementation of the described embodiments and variants is within the abilities of those skilled in the art based on the functional indications given hereabove.

1. A HEMT transistor comprising:a first semiconductor layer; a
nda gate arranged on a first surface of the first semiconductor layer,
wherein the gate comprises an alternation of at least two first layers and of at least three second layers, the at least two first layers being doped with magnesium and with at least one dopant element selected from among silicon and oxygen and the at least two first layers have a dopant element concentration higher than the dopant element concentration in the at least three second layers.

2. The HEMT transistor of claim 1, wherein the gate comprises at least four first layers and at least five second layers.

3. The HEMT transistor of claim 1, wherein each first layer is in contact with an overlying second layer and an underlying second layer.

4. The HEMT transistor of claim 1, wherein a magnesium concentration in the at least two first layers is higher than 1.1017 atoms/cm³.

5. The HEMT transistor of claim 1, wherein at least one of an oxygen and a silicon concentration in the at least two first layers is higher than 1.1016 atoms/cm³.

6. The HEMT transistor of claim 1, wherein a magnesium concentration in the at least three second layers is lower than 1.1017 atoms/cm³.

7. The HEMT transistor of claim 1, wherein a lower surface of the gate corresponds to a lower surface of a second lower layer.

8. The HEMT transistor of claim 1, wherein an upper surface of the gate corresponds to an upper surface of a second upper layer.

9. The HEMT transistor of claim 8, wherein the second upper layer has a greater thickness than other second layers of the gate.

10. The HEMT transistor of claim 9, wherein the gate comprises, between the second upper layer and a first lower layer, an aluminum nitride layer, said aluminum nitride layer being in contact with the second upper layer.

11. The HEMT transistor of claim 1, wherein the at least three second layers all have a same thickness.

12. The HEMT transistor of claim 1, wherein the gate further comprises an alternation of at least two third layers and of at least three fourth layers, the at least two third layers being predominantly doped with one of a silicon dopant element or oxygen dopant element, and the at least two third layers having a dopant element concentration higher than the dopant element concentration in the at least three fourth layers,
wherein the alternation of the at least two first layers and the at least three second layers is arranged in a lower portion of the gate and the alternation of the at least two third layers and the at least three fourth layers is arranged in an upper portion of the gate, and
wherein the at least two first layers are predominantly doped with magnesium dopant elements.

13. A method of forming a HEMT transistor comprising the following successive steps:
a) forming a first semiconductor layer;
b) forming at least two first layers in alternation with at least three second layers so as to create a gate on a first surface of the first semiconductor layer, wherein the at least two first layers are doped with magnesium and with at least one dopant element selected from among silicon and oxygen, and the at least two first layers have a dopant element concentration higher than the dopant element concentration in the at least three second layers.
